(19) United States
(12) Patent Application Publication
(10) Pub. No.: US 2026/0182278 A1
(43) Pub. Date: Jun. 25, 2026

(54) ATOMIC LAYER ETCHING OF III-V MATERIALS

(71) Applicant: Commissariat à I'Énergie Atomique et aux Énergies Alternatives, Paris (FR)

(72) Inventor: Stéphane Cadot, Grenoble (FR)

(73) Assignee: Commissariat à I'Énergie Atomique et aux Énergies Alternatives, Paris (FR)

(21) Appl. No.: 19/415,634

(22) Filed: Dec. 10, 2025

(30) Foreign Application Priority Data
Dec. 19, 2024 (FR) FR2414581

(51) Int. Cl. H10P 50/24; H10D 30/01; H10H 20/01

(52) U.S. Cl. CPC H10P 50/246; H10D 30/015; H10H 20/017

(57) ABSTRACT

A method of ALE etching of a III-V material including the following steps: a) placing in an enclosure a structure including a layer of III-V material, b) implementing, in the enclosure, at an etching temperature, one or more times the following ALE cycle: oxidizing a surface of the layer of III-V material with an oxidizing gas, whereby an oxide layer is formed, purging the enclosure with an inert gas flow, exposing the formed oxide layer to thionyl chloride vapor to etch the oxide layer, and purging the enclosure with an inert gas flow.

### CROSS REFERENCE TO RELATED APPLICATIONS

This application claims priority to French application number 2414581, filed Dec. 19, 2024. The contents of this application is incorporated by reference in its entirety.

### TECHNICAL FIELD

The present disclosure generally concerns the field of microelectronics, and more particularly methods of etching III-V materials. The invention is particularly advantageous for the manufacturing of power devices or optoelectronic devices.

### PRIOR ART

III-V materials (GaN, InGaN, AlGaN, AlN, InN, GaAs, InGaAs, etc.) are used for the manufacturing of optoelectronic devices (high-brightness micro-LEDs) or of power transistors (HEMTs, for ‘high electron mobility transistors’).

In the manufacturing method, these materials are etched to form cavities or patterns (contact holes in the case of transistors or definition of pixels in the case of micro-LEDs). The etching needs to be fast and directional (anisotropic). It is mainly based on the use of plasmas based on BCl₃, Cl₂ or on a mixture of these two compounds so as to form volatile compounds of the metals to be etched (mainly GaCl₃, InCl₃, and AlCl₃). The forming of compounds however requires high plasma energies, which makes the etching process rather invasive and leads to the forming of surface defects, or even to an amorphization of the surface of the III-V material after etching. This etch step is generally followed by a removal of the lithography resin and then by a cleaning of carbon residues by calcination (O₂ plasma). This step may also alter the III-V material at the surface (forming of an oxide layer).

The presence of these surface defects is critical to the performance of the previously-mentioned devices. Indeed, in the case of a power transistor, the presence of defects linked to plasma etching, surface oxidation, or resin residues increases the contact resistance at the metal/III-V interface, thereby degrading the electrical performance of the device and, in the case of micro-LEDs, the defects generate non-radiative charge recombination on the sides of the cavities between pixels, considerably decreasing the quantum efficiency of the LED.

In order to eliminate these defects, post-etching cleaning may be performed by a wet process (HCl or hydrofluoric acid buffer solution (BOE)). Wet cleaning leads to the obtaining of a clean and deoxidized surface. However, such a cleaning needs to be quickly followed by the next step to avoid oxidizing the cleaned surface before depositing the contact metal or the passivation layer.

Alternatively, the post-etching cleaning may be performed by a dry process, using an atomic layer etching (ALE) process. The advantage of this type of process is that it can be carried out directly in vapor deposition equipment, thus enabling to carry out in quick succession (without exposing the device back to air) the post-etching cleaning and the deposition step.

For example, U.S. Pat. No. 8,124,505 B1 describes a method of etching, in atomic layers, GaN and other III-V materials, in which the material is first oxidized on the surface by an O₂ plasma, after which the formed oxide layer is selectively etched by a BCl₃ plasma. It should be noted that both steps of the method require the use of plasma, which is not ideal for the obtaining of a surface free of structural defects

U.S. Pat. No. 10,056,264 B2 describes an alternative method of atomic layer etching (ALE) of GaN and other III-V materials based on the use of a BCl₃/Cl₂ mixture to chlorinate the surface of the material, followed by a selective vaporization of the chlorinated layer by an inert gas plasma. This method has the disadvantage of ending the sequence with a plasma likely to generate structural defects in the III-V material.

The article by Chittock et al. (“Isotropic atomic layer etching of GaN using SF₆ plasma and Al(CH₃)₃”, J. Appl. Phys. (2023) 134, 075302) discloses a GaN ALE process based on the alternation of an SF₆ plasma and on an exposure to trimethylaluminum (TMA) vapor. The GaN surface is first fluorinated by an SF₆ plasma, after which the surface fluoride is vaporized in the presence of TMA via an exchange reaction which enables to form volatile fluoromethyl derivatives of aluminum and gallium (AlF(CH₃)₂ and GaF(CH₃)₂). This method can be considered gentler than those previously described in that the TMA etching step is carried out chemically (without plasma).

### SUMMARY OF THE INVENTION

There exists a need to have a III-V material etching method overcoming the disadvantages of the prior art and, in particular, allowing isotropic etching of the III-V material without generating defects.

This object is achieved by a method of ALE etching of a III-V material comprising the following steps:
a) placing in an enclosure a structure comprising a substrate covered by a layer of III-V material,
b) implementing, in the enclosure, at an etching temperature, one or more times the following atomic layer etching cycle:
oxidizing a surface of the layer of the III-V material with an oxidizing gas, whereby an oxide layer is formed,
purging the enclosure with an inert gas flow,
exposing the formed oxide layer to thionyl chloride vapor to etch the oxide layer,
purging the enclosure with an inert gas flow,
c) preferably, depositing a layer of interest on the surface of the etched layer of III-V material.

According to a specific embodiment, the oxidizing gas is oxygen, ozone, or nitrogen dioxide.

According to a specific embodiment, the etching temperature is in the range from 20° C. to 1,000° C., preferably from 200° C. to 600° C.

According to a specific embodiment, the III-V material is free of aluminum, the III-V material being, for example, GaN or InGaN, and the etching temperature is preferably in the range from 200° C. to 400° C., more preferably from 300° C. to 400° C.

According to a specific embodiment, the cycle comprises an injection of water vapor simultaneously with the injection of oxidizing gas or after the injection of oxidizing gas.

According to a specific embodiment, the III-V material comprises aluminum, the III-V material being, for example, AlGaN or AlN, and the etching temperature is preferably in the range from 300° C. to 600° C., more preferably from 400° C. to 600° C.

This object is also achieved by a method of manufacturing a power device, for example a transistor, preferably an HEMT-type transistor, comprising a substrate covered by a GaN layer and one or more additional layers made of III-V material selected from among AlGaN and AlN, holes extending through the additional layer or layers and opening into the GaN layer, the through holes having been formed by a reactive ion etching step, the method comprising the following steps:
a) placing the device in an enclosure,
b) implementing, in the enclosure at an etching temperature preferably in the range from 200° C. to 600° C., one or more times the following cycle of ALE steps to perform a post-etching cleaning:
exposing the device to an oxidizing gas, whereby an oxide layer is formed on a surface of the GaN layer exposed to the oxidizing gas, where a surface of the additional layer(s) may also be oxidized,
purging the enclosure with an inert gas flow,
exposing the device to thionyl chloride vapor to selectively etch the oxide layer of the GaN layer,
purging the enclosure with an inert gas flow,
c) depositing in the through holes a layer of interest, particularly a metal layer, for example made of TiN, or a layer of dichalcogenide, for example made of VS₂, the layer of interest being in contact with the etched surface of the GaN layer, step c) being carried out in the enclosure used in step b).

This object is also achieved by a method of manufacturing an optoelectronic device, for example a micro-LED, comprising a substrate covered by a stack comprising an n-doped GaN layer, quantum wells, for example made of InGaN/GaN, a p-doped GaN layer, and a layer of transparent conductive oxide, the stack having been etched by reactive ion in order etching to form pixels, the n-doped GaN layer being partially etched, the method comprising the following steps:
a) placing the device in an enclosure,
b) implementing, in the enclosure at an etching temperature, preferably in the range from 200° C. to 600° C., one or more times the following cycle of ALE steps to perform a post-etching cleaning:
exposing the device to an oxidizing gas, whereby a surface of the stack exposed to the oxidizing gas is oxidized and an oxide layer is formed,
purging the enclosure with an inert gas flow,
exposing the device to thionyl chloride vapor to etch the oxide layer,
purging the enclosure with an inert gas flow,
c) depositing between the pixels and on the flanks of the pixels, a dielectric layer, for example made of SiO₂, Al₂ O₃, SiN, or AlN, step c) being carried out in the enclosure used in step b).

This object is also achieved by a device comprising a substrate covered by a layer of III-V material, a layer of interest, for example a metal contact layer, made of dichalcogenide, or a passivation layer, for example made of oxide or nitride, being in contact with the layer of III-V material, the surface of the III-V material layer in contact with the layer of interest being deoxidized.

This object is also achieved by a power device, for example a transistor, preferably an HEMT-type transistor, comprising a substrate covered by a GaN layer and at least one or more additional layers made of III-V material selected from among AlGaN and AlN, holes extending through the additional layer(s) and opening into the GaN layer, a layer of interest being formed in the through holes and in contact with the GaN layer, the layer of interest being a metal layer, for example made of TiN, or a layer of conductive dichalcogenide, for example made of VS₂, the surface of the GaN layer in contact with the layer of interest being deoxidized.

This object is also achieved by an optoelectronic device, for example a micro-LED, comprising a substrate covered by a stack comprising an n-doped GaN layer, quantum wells, a p-doped GaN layer, and a layer of transparent conductive oxide, the stack being etched in order to form pixels, the n-doped GaN layer being partially etched, a dielectric layer covering the n-doped GaN layer between the pixels and the flank of the pixels, the dielectric layer being in contact with the n-doped GaN layer, the dielectric layer being, for example, made of SiO₂, Al₂O₃, SiN, or AlN, the surface of the n-doped GaN layer in contact with the dielectric layer being deoxidized.

### BRIEF DESCRIPTION OF THE DRAWINGS

These features and advantages, as well as others, will be described in detail in the following description of specific embodiments, which is provided by way of example and is not intended to be limiting, in connection with the accompanying drawings, in which:

Views A), B), C), and D) of FIG. 1 show, schematically and in cross-section, several steps of a method of etching a III-V material, according to a specific embodiment of the invention;

FIG. 2 is a graph showing the free enthalpies of the reaction between SOCl₂ and various oxides resulting from the oxidation of III-V materials;

views A) and B) of FIG. 3 show, respectively, schematically and in cross-section, an HEMT power transistor (the dotted lines show the 2D electron gas) and a micro-LED according to different specific embodiments of the invention;

FIGS. 4A and 4B are images obtained with an atomic force microscope of a GaN layer, respectively, before and after an atomic layer etching method according to another specific embodiment (5 μm×5 μm scale).

The various elements are not necessarily shown to a uniform scale in order to make the drawings more readable.

### DESCRIPTION OF EMBODIMENTS

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and have been described in detail.

Unless otherwise specified, when reference is made to two elements being connected to each other, this means directly connected without any intermediate elements other than conductors, and when reference is made to two elements being coupled to each other, this means that these two elements may be connected or may be connected via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

By in the range from X to Y, there is meant that limits X and Y are included.

The method which will be described in more detail hereafter, with reference to the accompanying drawings, is a purely thermal (that is, plasma-free) method of atomic layer etching (ALE) of III-V materials. It thus allows an isotropic etching of III-V materials without generating defects. It is particularly adapted for removing the first few nanometers of surface which have been damaged by the plasma during the etching of pattern in devices based on III-V materials.

The method comprises the following steps:
a) placing in an enclosure a structure comprising a substrate 10 covered by a layer of III-V material 100, where the III-V material may be covered by a layer of native oxide 101 (view A) of FIG. 1),
b) implementing, in the enclosure, at an etching temperature preferably in the range from 20° C. to 1,200° C., more preferably from 20° C. to 1,000° C., and most preferably from 200° C. to 1,000° C., one or more times a cycle of atomic layer etching (ALE), whereby the surface of III-V material layer 100 is etched (views B) and C) of FIG. 1),
c) preferably, depositing a layer of interest 150 (for example, a contact or passivation layer) on the etched surface (view D) of FIG. 1).

The ALE cycle (or ALE sequence) consists of cyclically repeating the following steps:
1) Exposure of the surface of III-V material 100 to an oxidizing gas (view B) in FIG. 1), whereby an oxidized surface 110 is formed,
2) Purging of the reactor with an inert gas flow,
3) Exposure of the oxide 110 of the III-V material to a thionyl chloride vapor (view C) in FIG. 1),
4) Purging of the reactor with an inert gas flow.

The repeating of steps 1) to 4) forms an ALE cycle. The etching rate of the III-V material is expressed in nm/cycle or Å/cycle and corresponds to the average thickness of III-V material etched for each ALE cycle (average over a plurality of cycles). Steps 1) to 4) are repeated until the desired thickness is removed.

The method implements a first step of surface oxidation of the III-V material in order to form a thin oxide layer 110, followed by a second step during which the oxide layer is selectively etched (volatilized) by using a thionyl chloride (SOCl₂) vapor. By selectively etched, there is meant that only the oxide layer is etched. During this step, the III-V material is not etched. Only the few nanometers of surface which have been damaged and/or oxidized are removed. The surface of the III-V material is thus cleaned and deoxidized.

Oxidation step 1) is limited by the diffusion of the oxidizing gas and remains very superficial at the temperature used for the method. During this step, the VA-group elements are oxidized and the most volatile of them are eliminated (in NO, NO₂, P₄O₆, P₂O₅, . . . form), or etched during step 3) for the less volatile ones (As₂O₃, Sb₂O₃, Bi₂O₃).

Etch step 3) selectively etches the oxide formed during step 1) via the forming of volatile chlorides of group-IIIA or VA elements (GaCl₃, InCl₃, AlCl₃, AsCl₃, SbCl₃, BiCl₃), and the removal of oxygen in the form of sulfur dioxide (SO₂).

The chemical equation of the etching reaction is the following: M₂O₃+3 SOCl₂(g)→2 MCl₃(g)+3 SO₂(g) (with M the metal or pnictogen element).

Thionyl chloride does not etch (or very lightly etches) III-V materials. It reacts selectively with oxides, which enables to form an atomic layer by atomic layer etching in which each step (oxidation and etching) is limited to the surface atoms of the material.

The oxidizing gas used in step 1) may be oxygen (O₂), ozone (O₃), nitrogen dioxide (NO₂), or any other compound capable of releasing molecular or radical oxygen at the process temperature. The oxidizing gas may be introduced into the reactor, pure or diluted in an inert gas.

It is possible to inject water in the form of vapor simultaneously with the injection of oxidizing gas or consecutively to the injection of oxidizing gas.

The time of exposure of the III-V material to the oxidizing gas is adjusted according to the process temperature in order to ensure a self-limiting oxidation (that is, the oxide layer formed at the end of step 1) is sufficiently thick to act as a diffusion barrier to the oxidizing gas, thus stopping the oxidation process). This ensures an identical thickness of the oxide layer at any point of the surface of the material.

The thickness of the oxidized layer is typically smaller than 5 nm. In certain cases, the oxidation may be limited to the sole atoms exposed at the surface of the sample (case where the III-V material itself acts as a barrier to the diffusion of the oxidizing gas).

The etching gas (SOCl₂ vapor) introduced in step 3) is generated by evaporating a liquid source of SOCl₂. Mass transport is ensured either by the difference between the pressure of the reactor and that of the SOCl₂ source, or by an inert gas flow. Alternatively, thionyl chloride may be introduced into the reactor by direct injection. The time of exposure to the SOCl₂ vapor of the material to be etched is adjusted to ideally allow complete etching of the oxide formed during oxidation step 1). This complete etching of the oxide layer ensures a good process uniformity and enables to obtain a completely deoxidized III-V material surface at the end of the ALE etching process. It is facilitated by the ability of thionyl chloride to react selectively with oxides.

According to an alternative embodiment, the ALE cycle comprises subsequent steps during which steps 3) and 4) are repeated once again.

A plurality of exposures to SOCl₂ can enable to guarantee complete removal of the oxide formed during the oxidation step.

Oxidation step 1) and etch step 3) are separated by purges enabling to remove reaction by-products (volatile oxides during the oxidation step and volatile chlorides during the etch step) and to prevent mixing between the two precursors. This purge consists of introducing a flow of inert gas or maintaining the reactor under dynamic vacuum for a sufficiently long time to allow complete evacuation of the precursors and gaseous reaction by-products introduced or generated during the previous step.

The purge steps are indispensable to prevent the mixing of the different precursors. In the case where the precursors would be mixed in the reactor, the etching would occur continuously (etching of the oxide as it is generated). In the case where the oxidizing gas and the thionyl chloride are introduced sequentially and not mixed, an excellent uniformity and an atomic-scale control of the etching are obtained.

The neutral gas used in step 2) may be identical to the neutral gas used in step 4). Preferably, the gases are identical. The gases may be selected from among nitrogen or a noble gas such as helium or argon.

The neutral gas may be used as a carrier gas (or dilution gas) for the reactive species used during the oxidation (step 1) or etch (step 3) steps.

The different steps of the method will now be described in more detail.

Before step a), the deposition chamber may be passivated, for example, by a deposition of SiO₂, alumina, or a mixed oxide of aluminum and silicon (AlSiOₓ) in order to protect the metal components of the reactor from corrosion by SOCl₂.

The structure provided at step a) comprises a substrate 10 covered by a layer of III-V material 100 and optionally by one or more additional layers 200, 300, 400, 500, 600, 700. The additional layer(s) may be made of a III-V material identical or different from the III-V material of layer 100.

The III-V materials may contain aluminum or be aluminum-free. The III-V materials are, for example, selected from among GaN, InGaN, AlGaN, AlN, InN, GaAs, and InGaAs. The III-V materials may be doped or undoped.

Patterns may be formed in the structure, for example to delimit pixels or create holes allowing contact to be made on the sides of the III-V material.

The structuring may, for example, result from a step of reactive ion etching (RIE). The gases used for the etching are, for example, chlorinated gases.

The layer of III-V material 100 may be covered by a native oxide layer 101. This layer will disappear during the implementation of step b).

Substrate 10 is, for example, made of silicon or aluminum. The substrate may be passivated during step 1).

Step a) is a step of thermalization of the material at the process temperature. The temperature to which the substrate is heated during step a) is preferably identical to the temperature of step b) and identical to the temperature during step c).

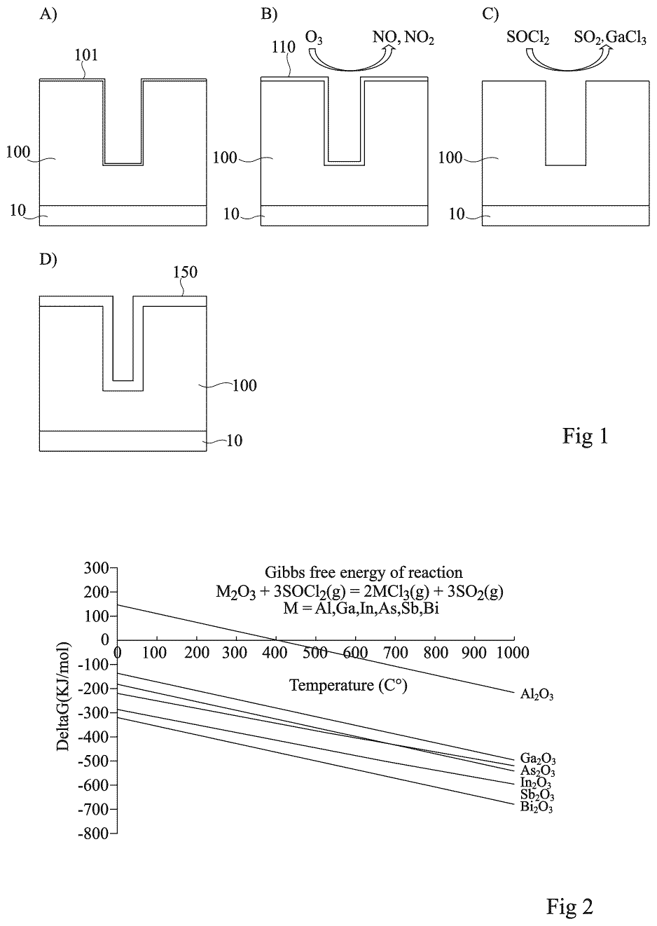

The temperature of the substrate during step b) depends on the material to be etched (FIG. 2). It is preferably higher than 20° C. It may be in the range from 20° C. to 1,200° C., preferably from 200° C. to 1,000° C., and even more preferably from 200° C. to 600° C. Preferably, it is in the range from 200° C. to 400° C., even more preferably from 300 to 400° C., for III-V materials containing no aluminum (for example, GaN, InGaN). Preferably, it is higher than 300° C. (for example, between 300° C. and 600° C.) and even more preferably higher than 400° C. (for example, between 400° C. and 1,000° C. or between 400° C. and 600° C.) for those containing aluminum (for example, AlN, AlGaN).

Thus, at a temperature lower than 400° C., for example at 350° C., it will for example be possible to selectively etch GaN or InGaN over AlN or AlGaN. This is particularly advantageous in the case of a structure comprising a layer of aluminum-free III-V material 100 and one or more additional layers 200, 300 of III-V material comprising aluminum (view B) in FIG. 3). The implementation of step b) at a temperature lower than 400° C. results in the selective etching of aluminum-free III-V material 100. The additional layer(s) 200, 300 comprising aluminum are not etched. As will be seen hereafter, this selective etching is particularly advantageous to manufacture microelectronic devices.

Preferably, the temperature during the etching (step b)) is identical to the deposition temperature (step c)) which will follow. For example, the temperature during steps b) and c) is in the range from 300° C. to 400° C. for aluminum-free III-V materials, which is ideal for the following on with a method of CVD or ALD deposition of most common metals or dielectrics (SiO₂, SiN, Al₂O₃, AlN, HfO₂, TIN, Ti(Al) C, etc.,).

During step b), the working pressure is in the range, for example, from 0.1 Pa to 1,000 hPa, preferably from 0.1 hPa to 50 hPa.

During step c), a layer of interest 150 (conductive layer or dielectric layer) is deposited over the etched surface.

Steps b) and c) may be carried out in the same enclosure, without exposing the material to air during deposition, in order to avoid the presence of oxide at the interface. For certain materials, this enables to form a van der Waals interface (without covalent bonds), and thus not to alter the surface state of the III-V material during the forming of the layer of interest 150.

The surface of the III-V materials thus etched, and in contact with the layer of interest, is deoxidized (that is, oxygen-free).

The layer of interest 150 may be a metal electrode, for example, based on TIN, TiC, Ti(Al) C, VN, VC, NbN, TaN, MON, WN, Ni, Co, Pt, Ru. Such metals may be deposited by ALD and used as contacts on transistors based on III-V materials (mainly GaN/AlGaN). According to another alternative embodiment, the layer of interest is a layer of conductive dichalcogenides such as VS₂, VSe₂, NbS₂, NbSe₂, TaS₂, TiS₂. These metals or semi-metals may be particularly advantageous as contacts in power transistors.

According to another alternative embodiment, the layer of interest 150 is made of a dielectric material such as SiO₂, Al₂O₃, HfO₂, ZrO₂, SiN, or AlN. Such dielectric materials may be deposited by ALD and used as electrical insulators on III/V-based pixels, for micro-LED applications, for example.

To form the SiO₂ or Al₂O₃ dielectric layer, it is also possible to first deposit a barrier layer of SiN or AlN (of small thickness, typically in the range from 1.5 to 2 nm) so as to protect the surface of the III-V material from oxidation. The subsequent deposition of SiO₂ or Al₂O₃ will partially oxidize this barrier layer to form a passivation layer consisting mainly of oxide, while preserving the surface of the III-V material.

Steps a), b), and c) may be directly implemented in most vacuum deposition reactors, which enables to follow on without exposure to air the ALE surface preparation of the III-V material and the subsequent metal or dielectric deposition in the device manufacturing method.

In particular, the ALE cycle is implemented in a vapor phase deposition reactor, ideally of ALD (atomic layer deposition) or CVD (chemical vapor deposition) type, preferably modified to allow sequential delivery of the precursors.

The isotropic and self-limiting nature of ALE also enables to implement the method in batch-type reactors.

The previously-described etching process may be used to manufacture a device, for example a power device or an optoelectronic device, comprising a substrate 10 covered by a first layer 100 of a first III-V material and at least one or more additional layers 200, 300, 500, 600 made of III-V material identical or different from the III-V material of the first layer 100.

The method may comprise the following steps:
a) placing the device in an enclosure,
b) implementing one or more times the following cycle of ALE steps at an etching temperature:
exposing the device to an oxidizing gas, whereby oxide layers are formed on the surfaces of the III-V materials exposed to the oxidizing gas,
purging the enclosure with an inert gas flow,
exposing the device to thionyl chloride (SOCl₂) vapor to etch at least the oxide layer 110 formed on the first III-V material of the first layer 100,
purging the enclosure with an inert gas flow,
c) optionally, depositing a layer of interest 150 at least on the surface of the first etched III-V material.

The atomic layer etching process is particularly relevant to decrease the density of defects at the III-V/metal or III-V/dielectric interfaces at the contacts (source and drain) in power transistors, particularly made of GaN/AlGaN (view A) of FIG. 3), or for optoelectronic devices, particularly for the passivation of the flanks of the pixels in GaN-based micro-LEDs (view B) in FIG. 3).

As a non-limiting illustration, the power device, particularly a power transistor for example of HEMT (High Electron Mobility Transistor) type, may be manufactured according to the following steps:
providing a structure successively comprising a substrate 10, a GaN layer 100, a stack formed of an AlGaN layer 200, an AlN layer 300, a SiN layer 400, a gate 20 being formed in the stack,
etching the stack and a portion of GaN layer 100 to form, on either side of gate 20, contact holes 30 for the source and drain regions, the etch step being preferably carried out by reactive ion etching,
performing a post-etching cleaning by selectively etching GaN 100 according to the ALE cycle of the previously-described step b),
depositing a contact layer 150 in the through holes, the contact layer being in contact with GaN layer 100 and being preferably made of metal or of conductive dichalcogenide (view A) of FIG. 3).

The post-etching cleaning and deposition step are advantageously performed in the same enclosure, without exposing the structure to air. The surface of GaN layer 100 in contact with the layer of interest 150 is deoxidized.

As a non-limiting example, the optoelectronic device, particularly a micro-LED, may be manufactured according to the following steps:
providing a structure successively comprising a substrate 10, an n-doped GaN layer 100, a stack formed of quantum wells (MQW) 500 made of III-V material (for example, InGaN/GaN wells), a p-GaN layer 600, a transparent conductive oxide layer 700 (for example, indium tin oxide (ITO)),
etching the stack and a portion of the n-doped GaN layer 100 to define the flanks of the pixels, the etch step being preferably carried out by reactive ion etching,
performing a post-etching cleaning by implementing the previously-described ALE cycle of step b), to etch the layers of III-V materials,
depositing an insulating layer of interest 150 on the flanks of the pixels and on the n-doped GaN layer 100, the insulating layer of interest 150 being a dielectric such as alumina, or any other insulating oxide or nitride (view B) in FIG. 3).

The cleaning and deposition steps are advantageously carried out in the same enclosure, without exposing the structure to air. The surface of the n-doped GaN layer 100 in contact with dielectric layer 150 is deoxidized.

The method is advantageously implemented for devices comprising an aluminum electrode. In particular, it is the lower electrode. Indeed, in the ALE etching sequence, aluminum is not etched because the oxidant forms an Al₂O₃ barrier layer and protect the electrode from etching with SOCl₂. The etching being selective, the aluminum electrodes are preserved and integration is facilitated. There is no need to use hard masks to protect the electrode during the process.

With the previously-described method, the resulting device has a very high quality at the interface between the III-V material and the passivation layer or the contact metal. The III-V material comprises no oxide at its surface. Further, by removing the surface layer which has been damaged, at least part of the structural defects formed during RIE etching are removed, which improves the performance of the final device.

### Illustrative and Non-Limiting Example

In this example, a GaN layer is etched by thermal ALE.

A thin layer of GaN epitaxially grown on silicon 111 is introduced into an ALD reactor equipped with an ozone generator and an SOCl₂ source maintained at 20° C. The working pressure is approximately 1 hPa with a continuous flow of 500 ml/min of nitrogen. The wafer is heated up to a 350° C. temperature and exposed to 600 cycles of the following etching sequence:
O₃ (19% in O2); 200 ml/min; 12 s
N₂ purge; 500 ml/min; 15 s
SOCl₂(g); 1,000 ml/min; 0.2s
N₂ purge 500 ml/min; 15 s

An ellipsometry measurement before and after etching indicates that 6.7 nm of GaN were etched, that is, an etching rate of 0.11 Å/cycle. The same sequence used without the oxidation step (600 cycles of SOCl₂ alone) did not result in any measurable etching of GaN, which confirms the ALE regime of the method and the total selectivity of the etching of Ga₂O₃ by SOCl₂ over GaN at 350° C.

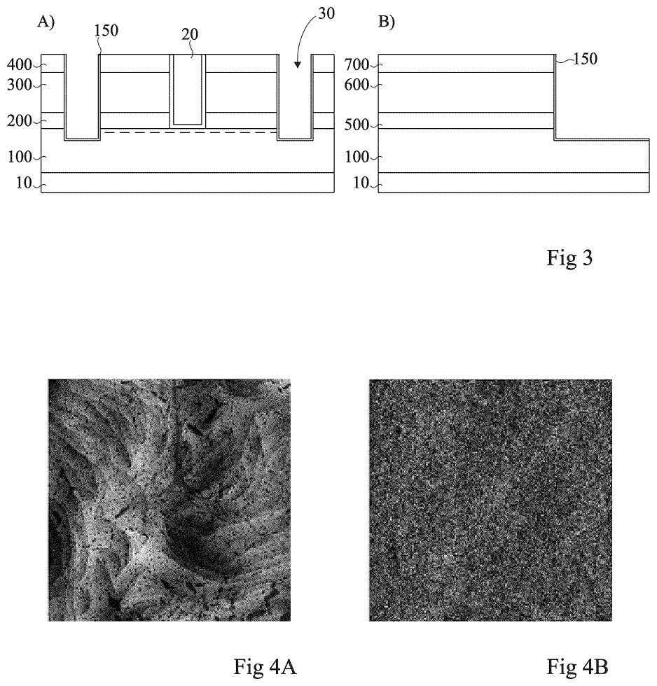

A characterization was also performed by AFM before and after the ALE process (FIGS. 4A and 4B). The images obtained by AFM confirm that the GaN layer after the ALE process is uniformly etched.

Various embodiments and variants have been described. The person skilled in the art will understand that certain features of these various embodiments and variants could be combined, and other variants will become apparent to the person skilled in the art.

Finally, the practical implementation of the described embodiments and variants is within the reach of the person skilled in the art on the basis of the functional indications given above.

1. Method of ALE etching of a III-V material comprising the following steps:
a) placing in an enclosure a structure comprising a substrate covered by a layer of III-V material,
b) implementing, in the enclosure, at an etching temperature, one or more times the following atomic layer etching cycle:
oxidizing a surface of the layer of III-V material with an oxidizing gas, whereby an oxide layer is formed,
purging the enclosure with an inert gas flow,
exposing the formed oxide layer to thionyl chloride vapor to etch the oxide layer,
purging the enclosure with an inert gas flow,
c) preferably, depositing a layer of interest on the surface of the etched layer of III-V material.

2. Method according to claim 1, wherein the oxidizing gas is oxygen, ozone, or nitrogen dioxide.

3. Method according to claim 1, wherein the etching temperature is in the range from 20° C. to 1,000° C., preferably from 200° C. to 600° C.

4. Method according to claim 1, wherein the III-V material is free of aluminum, the III-V material being, for example, GaN or InGaN, and wherein the etching temperature is preferably in the range from 200° C. to 400° C., more preferably from 300° C. to 400° C.

5. Method according claim 1, wherein the cycle comprises an injection of water vapor simultaneously with the injection of oxidizing gas or after the injection of oxidizing gas.

6. Method according to claim 1, wherein the III-V material comprises aluminum, the III-V material being, for example, AlGaN or AlN, and wherein the etching temperature is preferably in the range from 300° C. to 600° C., more preferably from 400° C. to 600° C.

7. Method of manufacturing a power device, for example a transistor, preferably an HEMT-type transistor, comprising a substrate covered by a GaN layer and one or more additional layers of III-V material selected from among AlGaN and AlN, holes extending through the additional layer and opening into the GaN layer, the through holes having been formed by a reactive ion etching step,
the method comprising the following steps:
a) placing the device in an enclosure,
b) implementing, in the enclosure at an etching temperature preferably in the range from 200° C. to 600° C., one or more times the following cycle of ALE steps to perform a post-etching cleaning:
exposing the device to an oxidizing gas, whereby an oxide layer is formed on a surface of the GaN layer exposed to the oxidizing gas, where a surface of the additional layer may also be oxidized,
purging the enclosure with an inert gas flow,
exposing the device to thionyl chloride vapor to selectively etch the oxide layer of the GaN layer,
purging the enclosure with an inert gas flow,
c) depositing in the through holes a layer of interest, in particular a metal layer, for example made of TiN, or a layer of dichalcogenide, for example made of VS₂, the layer of interest being in contact with the etched surface of the GaN layer,
step c) being carried out in the enclosure used during step b).

8. Method of manufacturing an optoelectronic device, for example a micro-LED, comprising a substrate covered by a stack comprising an n-doped GaN layer, quantum wells, for example made of InGaN/GaN, a p-doped GaN layer, and a layer of transparent conductive oxide, the stack having been etched by reactive ion etching, in order to form pixels, the n-doped GaN layer being partially etched,
the method comprising the following steps:
a) placing the device in an enclosure,
b) implementing, in the enclosure at an etching temperature preferably in the range from 200° C. to 600° C., one or more times the following cycle of ALE steps to perform a post-etching cleaning:
exposing the device to an oxidizing gas, whereby a surface of the stack exposed to the oxidizing gas is oxidized and an oxide layer is formed,
purging the enclosure with an inert gas flow,
exposing the device to thionyl chloride vapor to etch the oxide layer,
purging the enclosure with an inert gas flow,
c) depositing between the pixels and on the sides of the pixels a dielectric layer, for example made of SiO₂, Al₂O₃, SiN, or AlN, step c) being carried out in the enclosure used during step b).
